(19) United States
(12) Patent Application Publication
(10) Pub. No.: US 2026/0023418 A1
(43) Pub. Date: Jan. 22, 2026

(54) HINGE BARREL AIR DUCT

(71) Applicant: DELL PRODUCTS L.P., Round Rock, TX (US)

(72) Inventors: Allen B. McKittrick, Cedar Park, TX (US); Qinghong He, Austin, TX (US)

(21) Appl. No.: 18/780,045

(22) Filed: Jul. 22, 2024

(51) Int. Cl. G06F 1/20; G06F 1/16; H05K 7/20

(52) U.S. Cl. CPC G06F 1/203; G06F 1/1681; H05K 7/20145; G06F 2200/202

(57) ABSTRACT

A hinge barrel air duct has an elongated body configured to be positioned adjacent to the top panel of an information handling system having a chassis to which the top panel is pivotally connected by a hinge assembly. An exhaust intake is formed in a region of the elongated body of the hinge barrel air duct. The exhaust intake receives exhaust airflow expelled from the chassis. An exhaust outlet is formed in another region of the elongated body of the hinge barrel air duct. The exhaust outlet redirects exhaust airflow away from the chassis.

### FIELD OF THE DISCLOSURE

The present disclosure generally relates to information handling systems, and more particularly relates to a hinge barrel air duct for an information handling.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A hinge barrel air duct has an elongated body configured to be positioned adjacent to the top panel of a laptop computer having a chassis to which the top panel is pivotally connected by a hinge assembly. An exhaust intake is formed in a region of the elongated body of the hinge barrel air duct. The exhaust intake may receive exhaust airflow expelled from the chassis. An exhaust outlet is formed in another region of the elongated body of the hinge barrel air duct. The exhaust outlet may redirect exhaust airflow away from the chassis.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a perspective view of visible components of a laptop computer having a hinge barrel air duct according to an embodiment of the present disclosure.

FIGS. 2A and 2B are perspective views of an exhaust outlet of the hinge barrel air duct of FIG. 1 of according to an embodiments of the present disclosure

FIG. 3 is a cross-sectional view of a laptop computer having a hinge barrel air duct according to another embodiment of the present disclosure.

FIGS. 4A and 4B are cross-sectional views of a laptop computer having a hinge barrel air duct according to the embodiment of FIG. 3.

FIG. 5 is a partial cross-sectional view of a hinge barrel air duct according to another embodiment of the present disclosure.

FIG. 6 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

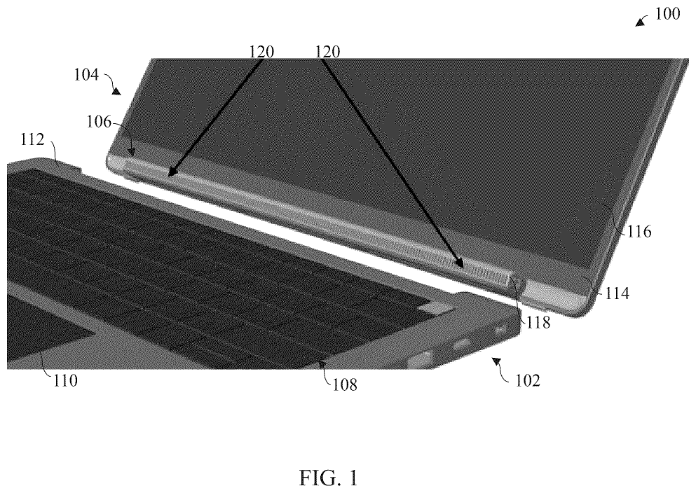

FIG. 1 illustrates an information handling system 100 according to at least one embodiment of the present disclosure. For purposes of this disclosure a information handling system is operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. More particularly, for purposes of this disclosure, a portable information handling system is a laptop computer, whose internal components may include random access memory (RAM), one or more processing resources such as a central processing unit (CPU) or hardware or software control logic, ROM, and/or other types of nonvolatile memory. Additional components may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

Information handling system 100 includes a chassis 102, top panel 104, and hinge barrel air duct 106. In an example, information handling system 100 may be a portable information handling system, such as a laptop compute. Although shown separated from chassis 102 for purpose of illustration, top panel 104 may be pivotally connected to chassis 102 by one or more hinges (e.g., three-knuckle drop hinges). Chassis 102 internally houses certain of the above-described components, such as a CPU, hardware or software control logic, ROM, and/or other types of nonvolatile memory, and the like. Information handling system 100 illustratively includes keyboard 108 and touchpad 110, both located on upper surface 112 of chassis 102. Front surface 114 of top panel 104 includes display screen 116 (e.g., liquid crystal display) embedded therein.

Hinge barrel air duct 106 is positioned adjacent to top panel 104 and may be connected thereto. As illustrated, hinge barrel air duct 106 includes an elongated body extending along a lower portion of top panel 104. The elongated body of hinge barrel air duct 106 forms an air duct for redirecting exhaust airflow generated within chassis 102 during operation, diverting the exhaust airflow away from the chassis. Exhaust intake 118 is formed in a region of the elongated body. In an open position with top panel 104 raised, exhaust intake is positioned to receive exhaust airflow expelled by chassis 102. In certain embodiments, exhaust intake 118 comprises multiple spaced-apart vents 120. In other arrangements, exhaust intake 118 may take other forms, such as one or more elongated openings extending lengthwise along the elongated body of hinge barrel air duct 106.

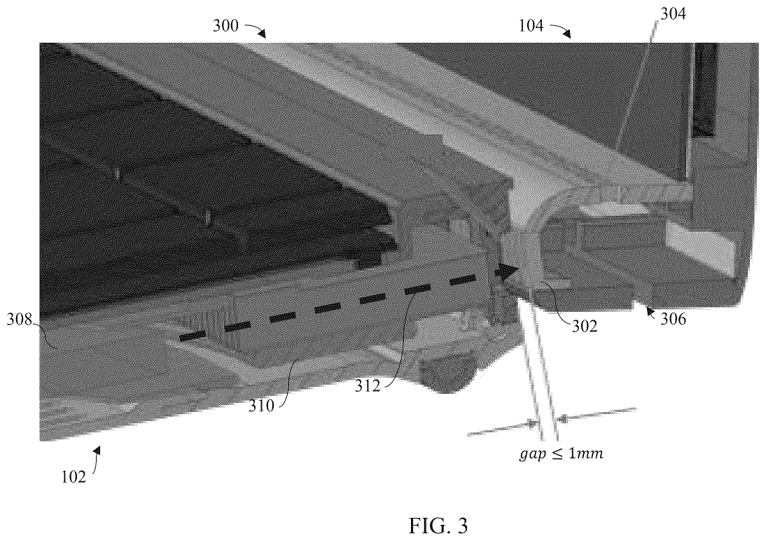

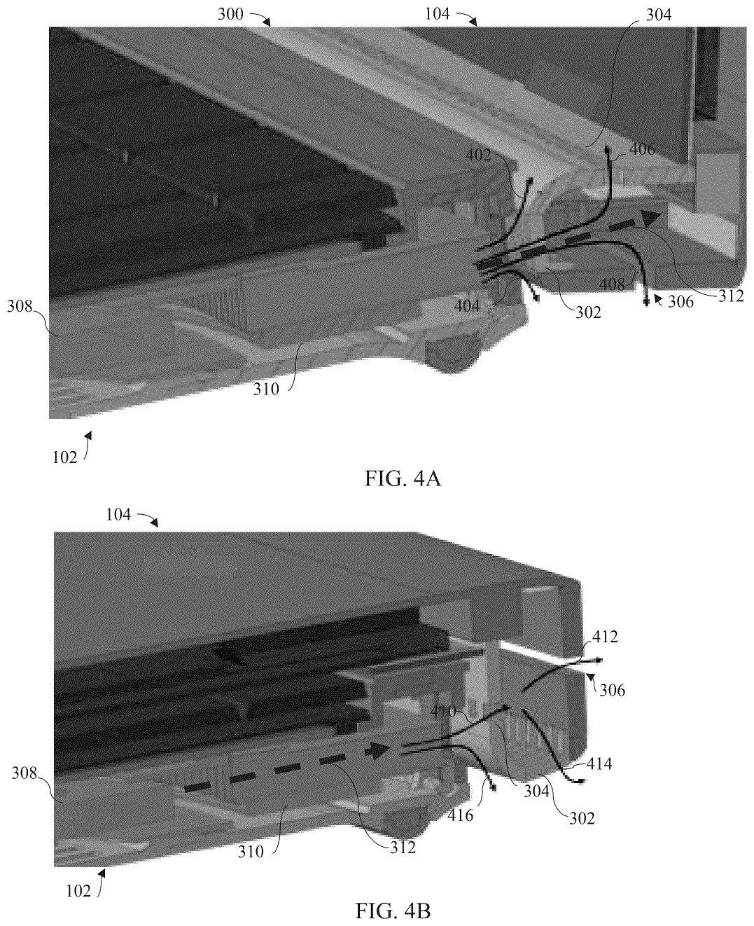

Although exhaust intake 118 is shown extending lengthwise along the elongated body of hinge barrel air duct 106, in other embodiments, the extent of the exhaust intake may be limited to a region of the elongated body lying substantially along a path of exhaust airflow that is drawn by a fan to a heat sink enclosed within chassis 102 and flowing outward from the chassis 102 as illustrated in portions of FIGS. 3, 4A, and 4B. In still other embodiments in which chassis 102 encloses multiple fan-and-heat sink combinations, exhaust intake 118 may include multiple isolated vents segments, each positioned along the elongated body of hinge barrel air duct 106 so as to lie within a specific path of exhaust airflow flowing out of the chassis from one of the plurality of fan-and-heat sink combinations enclosed within chassis 102.

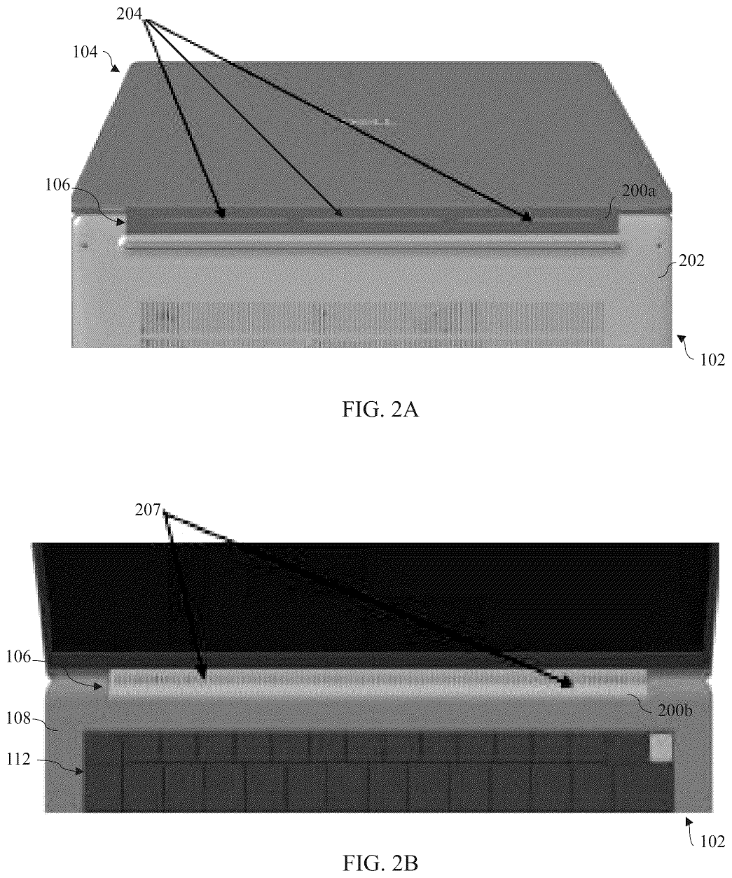

Referring additionally to FIGS. 2A and 2B, hinge barrel air duct 106 further includes one or more exhaust outlets that redirect exhaust airflow flowing out of chassis 102, thereby diverting the exhaust airflow away from the chassis. In FIG. 2A, exhaust outlet 200a is formed in a region of hinge barrel air duct 106 relative to the region in which exhaust intake 118 is formed such that exhaust airflow is directed downward, away from bottom surface 202 of chassis 102 when top panel 104 is raised in an open position. Illustratively, exhaust outlet 200a includes distinct, elongated openings 204 that extend lengthwise along the elongated body of hinge barrel air duct 106. In other arrangements, however, exhaust outlet 200a may take other forms, such as multiple spaced-apart vents.

In FIG. 2B, exhaust outlet 200b is formed in a region of hinge barrel air duct 106 relative to that in which exhaust intake 118 is formed such that exhaust airflow is directed upward, away from upper surface 112 of chassis 102 when top panel 104 is in the open position. Illustratively, exhaust outlet 200b includes multiple spaced-apart vents. In other arrangements, however, exhaust outlet 200a may take other forms, such as elongated openings extending lengthwise along the elongated body of hinge barrel air duct 106. An advantage of the arrangement illustrated in FIG. 2B is that exhaust intake 118 and exhaust outlet 200b reverse roles in response to a rotation of top panel 104 relative to chassis 102—that is, when the top panel is closed exhaust outlet 200b is repositioned to receive exhaust airflow from chassis 102. Thus repositioned, exhaust outlet 200b can operate as an exhaust intake. Exhaust intake 118 is likewise repositioned and can operate by redirecting exhaust airflow downward, away from bottom surface 202 of chassis 102 and top panel 104.

FIG. 3 illustrates hinge barrel air duct 300 in accordance with another embodiment of the present disclosure. Hinge barrel air duct 300 may be substantially similarly to hinge barrel air duct 106 of FIGS. 1, 2A, and 2B. Hinge barrel air duct 300 includes an exhaust intake 302 on one side and distinct exhaust outlets 304 and 306 on two other sides. With top panel 104 open, exhaust intake 302 is positioned directly opposite the edge of chassis 102 out of which exhaust airflow is expelled from the chassis. Exhaust airflow may be drawn by fan 308 to heat sink 310 and then expelled. Exhaust intake 302, with top panel 104 open, is aligned with the edge of chassis 102 out of which exhaust airflow is expelled so that vents forming exhaust intake 302 lie substantially in path 312 along which the exhaust airflow flows. Exhaust outlet 304 is formed in the side of hinge barrel air duct 300 above exhaust intake 302 and exhaust outlet 306 is formed in an opposing side below exhaust intake 302. Exhaust outlets 304 and 306 redirect the exhaust airflow received through exhaust intake 302, diverting it away from chassis 102 and along top panel 104. In certain embodiments, a gap between hinge barrel air duct 300 and the edge of chassis 102 out which the exhaust airflow is expelled is no more than one millimeter.

Referring additionally to FIGS. 4A and 4B, certain operative aspects of hinge barrel air duct 300 are illustrated when top panel 104 is open and when it is closed. In FIG. 4A, with top panel 104 open, portions 402 and 404 of the exhaust airflow flow around hinge barrel air duct 300 and out of the gap between the hinge barrel air duct and the edge of chassis 102. Portions 406 and 408 of the airflow proceed directly into exhaust intake 302. Exhaust outlet 304 diverts portion 406 of the airflow upward and away from chassis 102 and along top panel 104, while exhaust outlet 306 diverts portion 408 downward and away from the chassis and along top panel.

In FIG. 4B, top panel 104 is in the closed position. Hinge barrel air duct 300 responds to the rotation of top panel 104 from the open position to the closed position by reversing the roles of exhaust intake 302 and exhaust outlet 304. The rotation aligns exhaust outlet 304 such that it lies substantially in path 312 along which exhaust airflow flows and is expelled from chassis 102. Exhaust outlet 304 then operates by receiving portion 410 of the exhaust airflow. Exhaust outlet 306 is reoriented as well and operates by redirecting portion 412 of the exhaust airflow in a direction substantially parallel with the direction of path 312 that the exhaust airflow takes flowing out from chassis 102. Exhaust intake 302, too, is reoriented by the rotation of top panel 104 and operates by redirecting portion 414 of the exhaust airflow downward and away from chassis 102. Portion 416 of the exhaust airflow flows downward through the gap between chassis 102 and hinge barrel air duct 300.

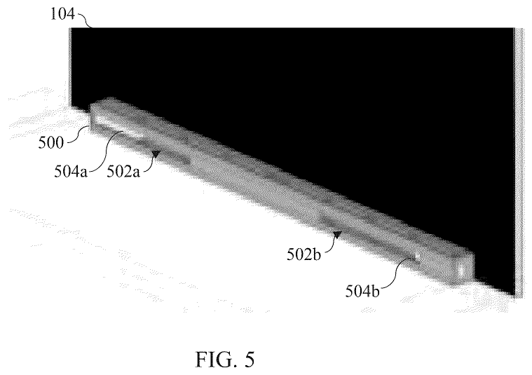

FIG. 5 illustrates a hinge barrel air duct 500 according to another embodiment of the present disclosure. Hinge barrel air duct 500, as illustrated, includes an elongated body having region(s) in which one or more exhaust intakes (not explicitly shown) are formed to receive at least a portion of the exhaust airflow expelled from a chassis of an information handling system. Additionally, hinge barrel air duct 500 may include region(s) in which one or more exhaust outlets are formed to divert the received exhaust airflow away from both the chassis and a top panel of the laptop computer. The top panel may be pivotally connected to the chassis by hinge assemblies (e.g., three-knuckle drop hinge assemblies). Each hinge assembly may include a hinge pin or shaft. In certain embodiments, as illustrated by hinge barrel air duct 500, the elongated body of the hinge barrel air duct may include internal cavities 502a and 502b. These open regions are configured to receive therein hinge pins 504a and 504b extending from respective hinge assemblies 502a and 502b.

The different embodiments of the hinge barrel air duct disclosed herein may be positioned adjacent to or connected with the bottom portion of a top panel in an information handling system, lying directly in the path of the exhaust airflow expelled from the chassis of the information handling system. The temperature of the exhaust airflow can elevate skin temperatures in common-touch areas of the information handling system, especially if a solid hinge cap is attached to the laptop's top panel, thus potentially trapping a portion of the exhaust airflow between the chassis and top panel. Conventional approaches have tended to focus on design adjustments, such as expanding the dimensions of the information handling system with a four-millimeter or greater gap between the chassis and a hinge cap over the hinge assemblies, or redesigning the chassis ledge, or even reducing the laptop's thermal design power (TDP). By contrast, the embodiments of the hinge barrel air duct disclosed herein mitigate the temperature effects of the exhaust airflow by diverting the exhaust airflow away from the chassis and top panel. Moreover, the gap between the hinge barrel air duct and chassis of the information handling system may be one millimeter or less without giving rise to concerns about trapping substantial portions of the exhaust airflow.

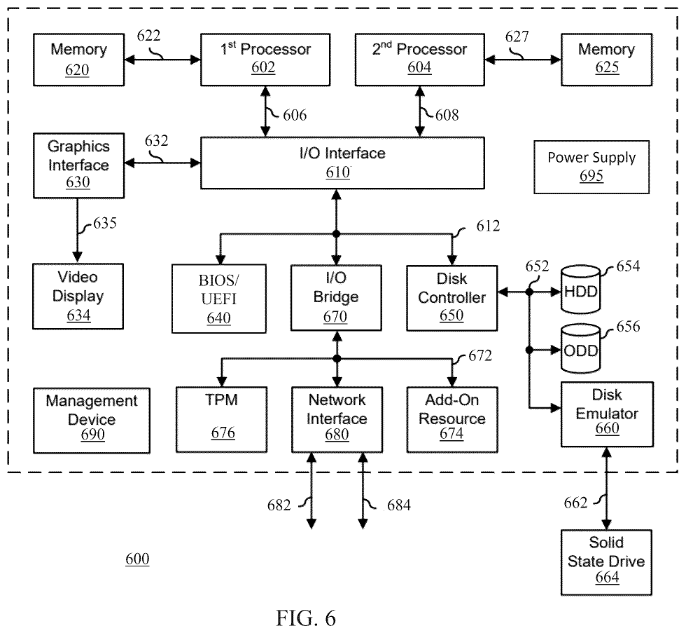

FIG. 6 shows a generalized embodiment of an information handling system 600 according to an embodiment of the present disclosure. Information handling system 600 may be substantially similar to information handling system 100 of FIG. 1. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 600 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 600 can include processing resources for executing machine-executable code, such as a central processing unit (CPU), a programmable logic array (PLA), an embedded device such as a System-on-a-Chip (SoC), or other control logic hardware. Information handling system 600 can also include one or more computer-readable medium for storing machine-executable code, such as software or data. Additional components of information handling system 600 can include one or more storage devices that can store machine-executable code, one or more communications ports for communicating with external devices, and various input and output (I/O) devices, such as a keyboard, a mouse, and a video display. Information handling system 600 can also include one or more buses operable to transmit information between the various hardware components.

Information handling system 600 can include devices or modules that embody one or more of the devices or modules described below and operates to perform one or more of the methods described below. Information handling system 600 includes a processors 602 and 604, an input/output (I/O) interface 610, memories 620 and 625, a graphics interface 630, a basic input and output system/universal extensible firmware interface (BIOS/UEFI) module 640, a disk controller 650, a hard disk drive (HDD) 654, an optical disk drive (ODD) 656, a disk emulator 660 connected to an external solid state drive (SSD) 664, an I/O bridge 670, one or more add-on resources 674, a trusted platform module (TPM) 676, a network interface 680, a management device 690, and a power supply 695. Processors 602 and 604, I/O interface 610, memory 620, graphics interface 630, BIOS/UEFI module 640, disk controller 650, HDD 654, ODD 656, disk emulator 660, SSD 664, I/O bridge 670, add-on resources 674, TPM 676, and network interface 680 operate together to provide a host environment of information handling system 600 that operates to provide the data processing functionality of the information handling system. The host environment operates to execute machine-executable code, including platform BIOS/UEFI code, device firmware, operating system code, applications, programs, and the like, to perform the data processing tasks associated with information handling system 600.

In the host environment, processor 602 is connected to I/O interface 610 via processor interface 606, and processor 604 is connected to the I/O interface via processor interface 608. Memory 620 is connected to processor 602 via a memory interface 622. Memory 625 is connected to processor 604 via a memory interface 627. Graphics interface 630 is connected to I/O interface 610 via a graphics interface 632 and provides a video display output 636 to a video display 634. In a particular embodiment, information handling system 600 includes separate memories that are dedicated to each of processors 602 and 604 via separate memory interfaces. An example of memories 620 and 630 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 640, disk controller 650, and I/O bridge 670 are connected to I/O interface 610 via an I/O channel 612. An example of I/O channel 612 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 610 can also include one or more other I/O interfaces, including an Industry Standard Architecture (ISA) interface, a Small Computer Serial Interface (SCSI) interface, an Inter-Integrated Circuit (I2C) interface, a System Packet Interface (SPI), a Universal Serial Bus (USB), another interface, or a combination thereof. BIOS/UEFI module 640 includes BIOS/UEFI code operable to detect resources within information handling system 600, to provide drivers for the resources, initialize the resources, and access the resources.

BIOS/UEFI module 640 includes code that operates to detect resources within information handling system 600, to provide drivers for the resources, to initialize the resources, and to access the resources.

Disk controller 650 includes a disk interface 652 that connects the disk controller to HDD 654, to ODD 656, and to disk emulator 660. An example of disk interface 652 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 660 permits SSD 664 to be connected to information handling system 600 via an external interface 662. An example of external interface 662 includes a USB interface, an IEEE 4394 (Firewire) interface, a proprietary interface, or a combination thereof. Alternatively, solid-state drive 664 can be disposed within information handling system 600.

I/O bridge 670 includes a peripheral interface 672 that connects the I/O bridge to add-on resource 674, to TPM 676, and to network interface 680. Peripheral interface 672 can be the same type of interface as I/O channel 612 or can be a different type of interface. As such, I/O bridge 670 extends the capacity of I/O channel 612 when peripheral interface 672 and the I/O channel are of the same type, and the I/O bridge translates information from a format suitable to the I/O channel to a format suitable to the peripheral channel 672 when they are of a different type. Add-on resource 674 can include a data storage system, an additional graphics interface, a network interface card (NIC), a sound/video processing card, another add-on resource, or a combination thereof. Add-on resource 674 can be on a main circuit board, on separate circuit board or add-in card disposed within information handling system 600, a device that is external to the information handling system, or a combination thereof.

Network interface 680 represents a NIC disposed within information handling system 600, on a main circuit board of the information handling system, integrated onto another component such as I/O interface 610, in another suitable location, or a combination thereof. Network interface device 680 includes network channels 682 and 684 that provide interfaces to devices that are external to information handling system 600. In a particular embodiment, network channels 682 and 684 are of a different type than peripheral channel 672 and network interface 680 translates information from a format suitable to the peripheral channel to a format suitable to external devices. An example of network channels 682 and 684 includes InfiniBand channels, Fibre Channel channels, Gigabit Ethernet channels, proprietary channel architectures, or a combination thereof. Network channels 682 and 684 can be connected to external network resources (not illustrated). The network resource can include another information handling system, a data storage system, another network, a grid management system, another suitable resource, or a combination thereof.

Management device 690 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 600. In particular, management device 690 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 600, such as system cooling fans and power supplies. Management device 690 can include a network connection to an external management system, and the management device can communicate with the management system to report status information for information handling system 600, to receive BIOS/UEFI or system firmware updates, or to perform other task for managing and controlling the operation of information handling system 600.

Management device 690 can operate off of a separate power plane from the components of the host environment so that the management device receives power to manage information handling system 600 when the information handling system is otherwise shut down. An example of management device 690 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 690 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A hinge barrel air duct for an information handling system having a chassis and a top panel pivotally connected thereto by a hinge assembly, the hinge barrel air duct comprising:
an elongated body configured to be positioned adjacent to the top panel;
an exhaust intake formed in a first region of the elongated body, wherein the exhaust intake receives exhaust airflow expelled from the chassis; and
an exhaust outlet formed in a second region of the elongated body, wherein the exhaust outlet redirects exhaust airflow away from the chassis.

2. The hinge barrel air duct of claim 1, wherein when the top panel is in a closed position relative to the chassis, the exhaust outlet to receive the exhaust airflow and the exhaust intake to redirect the exhaust airflow away from the chassis and the top panel.

3. The hinge barrel air duct of claim 1, wherein the exhaust outlet comprises a first exhaust outlet, and the hinge barrel air duct further includes a second exhaust outlet formed in a third region of the elongated body.

4. The hinge barrel air duct of claim 3, wherein, when the information handling system is in an open position, the first exhaust outlet redirects a portion of the exhaust airflow upward and away from the chassis and the second exhaust outlet directs another portion of the exhaust airflow downward and away from the chassis.

5. The hinge barrel air duct of claim 3, wherein, when the information handling system is in a closed position, the first exhaust outlet operates to receive the exhaust airflow, the second the exhaust outlet operates to redirect a portion of the exhaust airflow in a direction substantially parallel with a direction that the exhaust airflow flows out from the chassis, and the exhaust intake operates to redirect another portion of the exhaust airflow downward and away from the chassis.

6. The hinge barrel air duct of claim 1, wherein a rotation of the top panel away from the chassis creates a gap between the hinge barrel air duct and the chassis, the gap being less than or equal to 1 millimeter (mm).

7. The hinge barrel air duct of claim 1, wherein the exhaust intake is formed by a vent positioned substantially along a path of the exhaust airflow drawn by a fan through a heat sink enclosed within the chassis and outward from the chassis.

8. The hinge barrel air duct of claim 1, wherein the exhaust intake is formed by a plurality of vents, each of the plurality of vents positioned substantially along a path of the exhaust airflow out of the chassis from one of a plurality of fan-and-heat sink combinations enclosed within the chassis.

9. The hinge barrel air duct of claim 1, wherein the elongated body includes an internal cavity to receive therein a hinge pin that extends from the hinge assembly.

10. An information handling system (IHS) having a clamshell form factor, the IHS comprising:
a chassis, the chassis including:
a processor; and
a memory operatively coupled with the processor;
a top panel having embedded therein a display operatively coupled with the processor and memory, wherein the top panel and the chassis are pivotally connected by a hinge assembly; and
a hinge barrel air duct including:
an elongated body configured to be positioned adjacent to the top panel;
an exhaust intake formed in a first region of the elongated body, wherein the exhaust intake receives exhaust airflow expelled from the chassis; and
an exhaust outlet formed in a second region of the elongated body, wherein the exhaust outlet redirects the exhaust airflow away from the chassis.

11. The IHS of claim 10, wherein in response to a rotation of the top panel relative to the chassis, the exhaust outlet to receive the exhaust airflow and the exhaust intake to redirect the exhaust airflow away from the chassis and the top panel.

12. The IHS of claim 10, wherein the exhaust outlet comprises a first exhaust outlet, and the hinge barrel air duct further includes a second exhaust outlet formed in a third region of the elongated body.

13. The IHS of claim 12, wherein, when the IHS is in an open position, the first exhaust outlet redirects a portion of the exhaust airflow upward and away from the chassis and the second exhaust outlet directs another portion of the exhaust airflow downward and away from the chassis.

14. The IHS of claim 12, wherein, when the IHS is in a closed position, the first exhaust outlet receives the exhaust airflow, the second the exhaust outlet redirects a portion of the exhaust airflow in a direction substantially parallel with a direction that the exhaust airflow flows out from the chassis, and the exhaust intake redirects another portion of the exhaust airflow downward and away from the chassis.

15. The IHS of claim 10, wherein a rotation of the top panel away from the chassis creates a gap between the hinge barrel air duct and the chassis, the gap being less than or equal to 1 millimeter (mm).

16. The IHS of claim 10, wherein the exhaust intake is formed by a vent positioned substantially along a path of the exhaust airflow drawn by a fan through a heat sink enclosed within the chassis and outward from the chassis.

17. The IHS of claim 10, wherein the exhaust intake is formed by a plurality of vents, each of the plurality of vents positioned substantially along a path of the exhaust airflow out of the chassis from one of a plurality of fan-and-heat sink combinations enclosed within the chassis.

18. The IHS of claim 10, wherein the elongated body includes an internal cavity to receive therein a hinge pin that extends from the hinge assembly.

19. An information handling system (IHS) comprising:
a chassis, the chassis including:
a processor; and
a memory operatively coupled with the processor;
a top panel having embedded therein a display operatively coupled with the processor and memory, wherein the top panel and chassis are pivotally connected by a hinge assembly; and
a hinge barrel air duct including:
an elongated body configured to be positioned adjacent to the top panel;
a first exhaust outlet formed in a first region of the elongated body, wherein the first exhaust outlet redirects an exhaust airflow away from the chassis;
a second exhaust outlet formed in a second region of the elongated body, wherein the second exhaust outlet redirects the exhaust airflow away from the chassis and the top panel; and
an exhaust intake formed in a third region of the elongated body, wherein the third region is located between the first and second regions of the elongated body, and wherein the exhaust intake receives the exhaust airflow expelled from the chassis; and
wherein rotating the top panel away from the chassis creates a gap between the hinge barrel air duct and the chassis.

20. The IHS of claim 19, wherein, when the IHS is in a closed position, the first exhaust outlet receives the exhaust airflow, the second exhaust outlet redirects a portion of the exhaust airflow in a direction substantially parallel with a direction that the exhaust airflow flows out from the chassis, and the exhaust intake redirects another portion of the exhaust airflow downward and away from the chassis.
